(19) United States
(12) Patent Application Publication
(10) Pub. No.: US 2015/0004792 A1
(43) Pub. Date: Jan. 1, 2015

(54) METHOD FOR TREATING WAFER

(71) Applicant: UNITED MICROELECTRONICS CORP., HSINCHU (TW)

(72) Inventor: Chih-Cheng Chen, SINGAPORE (SG)

(21) Appl. No.: 13/927,326

(22) Filed: Jun. 26, 2013

(51) Int. Cl. H01L 21/02; H01L 21/311; B08B 3/08

(52) U.S. Cl. CPC H01L 21/02101; B08B 3/08; H01L 21/02274; H01L 21/31116; H01L 21/02266; H01L 21/02052; H01L 21/0206; H01L 21/0209; H01L 21/02334
USPC 438/710; 134/26; 438/778

(57) ABSTRACT

A method for treating a wafer is provided. The method includes at least the following steps. A plasma process is performed on a front surface of the wafer, and the wafer is cleaned. The wafer is cleaned by applying deionized water with dissolved CO₂ to the front surface of the wafer and applying a chemical solution to a back surface, opposite to the front surface, of the wafer.

### BACKGROUND

1. Technical Field

The disclosure relates in general to a method for treating a wafer, and more particularly to a cleaning process in a method for treating a wafer.

2. Description of the Related Art

In manufacturing processes for semiconductor devices, wafers are often cleaned by deionized water to remove contamination remained on the surfaces. However, charges remained on the surfaces of the wafers may cause serious issues, such as failure of gate oxide integrity (GOI) or gate oxide breakdown, which result in the failure of the semiconductor devices. Therefore, it is desirable to develop improved methods for treating wafers.

### SUMMARY OF THE INVENTION

The disclosure is directed to a method for treating a wafer. In the embodiments, deionized water with dissolved CO₂ is applied to a surface of the wafer after a plasma process is performed thereon, such that accumulated charges caused by the plasma process remained on the surface of the wafer can be released, and hence no defect occurs on the surface of the wafer, which is advantageous to the subsequent manufacturing processes.

According to an embodiment of the present disclosure, a method for treating a wafer is disclosed. The method includes at least the following steps. A plasma process is performed on a front surface of the wafer, and the wafer is cleaned. The wafer is cleaned by applying deionized water with dissolved CO₂ to the front surface of the wafer and applying a chemical solution to a back surface, opposite to the front surface, of the wafer.

The disclosure will become apparent from the following detailed description of the preferred but non-limiting embodiments. The following description is made with reference to the accompanying drawings.

### BRIEF DESCRIPTION OF THE DRAWINGS

FIGS. 1A-1C illustrate a method for treating a wafer according to a preferred embodiment of the disclosure;

FIGS. 2A-2B show a jet nozzle for supplying deionized water with dissolved CO₂ to a surface of the wafer according to a preferred embodiment of the disclosure; and

FIGS. 3A-3B show an atomized spray nozzle for supplying deionized water dissolved CO₂ to a surface of the wafer according to a preferred embodiment of the disclosure.

### DETAILED DESCRIPTION OF THE INVENTION

In the embodiments of the disclosure, deionized water with dissolved CO₂ is applied to a surface of the wafer after a plasma process is performed thereon, such that accumulated charges caused by the plasma process remained on the surface of the wafer can be released, and hence no defect occurs on the surface of the wafer, which is advantageous to the subsequent manufacturing processes. The embodiments are described in details with reference to the accompanying drawings. The procedures and details of the method of the embodiments are for exemplification only, not for limiting the scope of protection of the disclosure. Moreover, the identical elements of the embodiments are designated with the same reference numerals. Also, it is also important to point out that the illustrations may not be necessarily be drawn to scale, and that there may be other embodiments of the present disclosure which are not specifically illustrated. Thus, the specification and the drawings are to be regard as an illustrative sense rather than a restrictive sense.

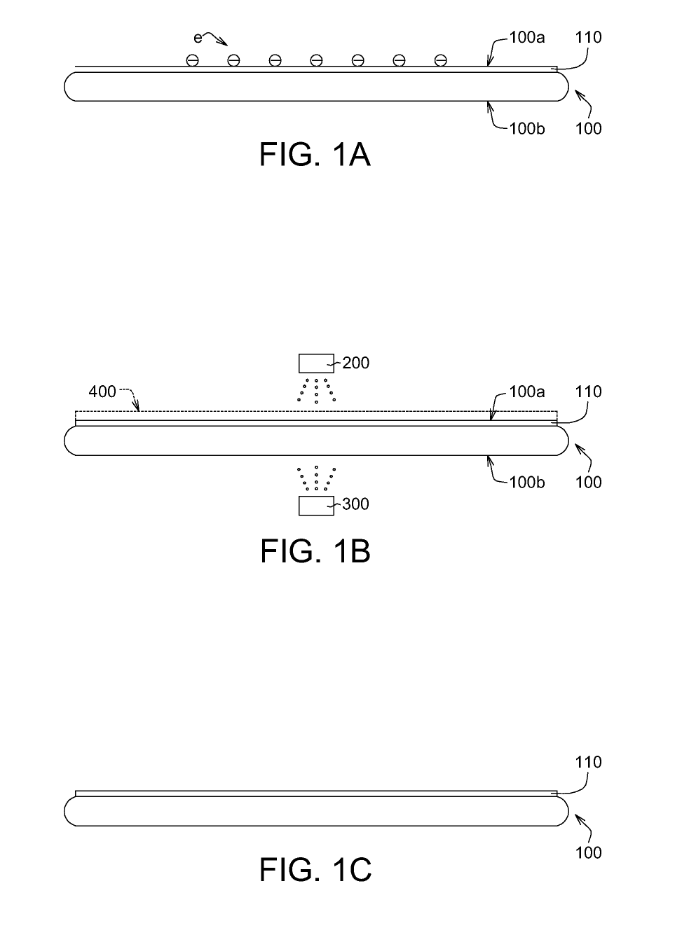

Referring to FIGS. 1A-1C, FIGS. 1A-1C illustrate a method for treating a wafer 100 according to a preferred embodiment of the disclosure. First, a plasma process is performed on a front surface 100a of a wafer 100. In the present embodiment, the plasma process may comprise at least one of a plasma-enhanced chemical vapor deposition (PECVD) process, a high density plasma chemical vapor deposition (HDPCVD) process, or a sputtering process. However, the plasma process may be any types of plasma process depending on the conditions applied and is not limited to the types aforementioned.

In the embodiment, as shown in FIG. 1A, the front surface 100a may be formed of a dielectric layer 110, such as an inter-metal dielectric (IMD) or an interlayer dielectric (ILD), and the dielectric layer 110 may be formed by the plasma process. The material of the dielectric layer 110 may include a dielectric material, such as silicon oxide or silicon nitride. The thickness of the dielectric layer 110 may be about 12 nm. As shown in FIG. 1A, after the plasma process is performed, a number of charges e are formed on the front surface 100a of the wafer 100. The charges e may be negative charges produced by the plasma process. However, the front surface 100a may be formed of any materials with a variety of applicable thicknesses formed by the plasma process depending on the conditions applied and is not limited to the materials and the thickness aforementioned.

Next, as shown in FIG. 1B, the wafer 100 is cleaned by applying deionized water with dissolved CO₂ to the front surface 100a and applying a chemical solution to a back surface 100b, opposite to the front surface 100a, of the wafer 100. In the embodiment, the wafer 100 may be any types of semiconductor wafer, and the cleaning process is performed after the plasma process.

In the embodiments of the present disclosure, as shown in FIG. 1B, deionized water with dissolved CO₂ and the chemical solution are applied with nozzles 200 and 300, respectively. The nozzles 200 and 300 may be independently a jet nozzle, an atomized spray nozzle, or a mega-sonic nozzle. That is, deionized water, deionized water dissolved with CO₂, the chemical solution, and IPA, which will be discussed afterward, may be applied to the surfaces of the wafer 100 with a jet nozzle, an atomized spray nozzle, or a mega-sonic nozzle, independently. While an atomized spray nozzle is utilized, pressurized N₂ gas is added for providing an atomic spray, and the proceeding velocity of the atomic spray is accelerated.

In the embodiments, the cleaning process may include the following steps. At first, deionized water with dissolved CO₂ is provided from the nozzle 200 to be applied to the front surface 100a of the wafer 100. Since the plasma process causes the occurrence of charges e on the front surface 100a of the wafer 100, when pure deionized water is applied to the front surface 100a, the accumulated negative charges on the front surface 100a in contact with the positive ions from pure deionized water generate defects on the surface 100a, such as C residues or bumps. In contrast, according to the embodiments of the present disclosure, the weak acidity provided by the dissolved CO₂ in deionized water releases the accumulated charges on the surface 100a, and hence no defects occur, which is advantageous to the subsequent manufacturing processes.

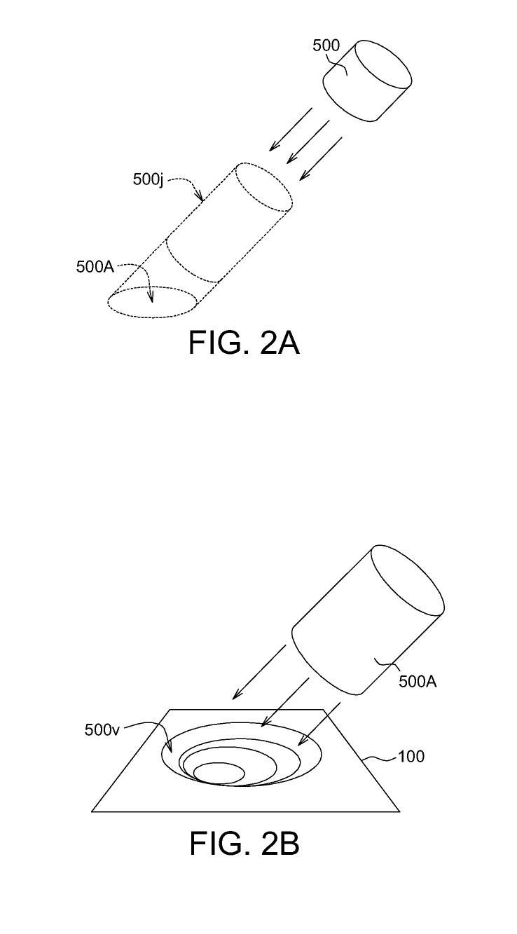

In an embodiment, the nozzle may be a jet nozzle. FIGS. 2A-2B show a jet nozzle 500 for supplying deionized water with dissolved CO₂ to a surface of the wafer 100 according to a preferred embodiment of the disclosure. The diameter of the jet nozzle 500 is about 0.1-0.2 mm, therefore, as shown in FIG. 2A, the effective cleaning area 500A is relatively small. On the contrary, as shown in FIG. 2B, the mass volume 500v of the jet 500j of deionized water with dissolved CO₂ ejected from the jet nozzle 500 is relatively strong, causing strong impact to the wafer 100, and hence the jet nozzle 500 is provided with an improved ability of removing particles from the surfaces of the wafer 100. In the embodiment, the jet nozzle 500 may be a high pressure jet nozzle, and particles with large sizes can be removed from the surfaces of the wafer more effectively.

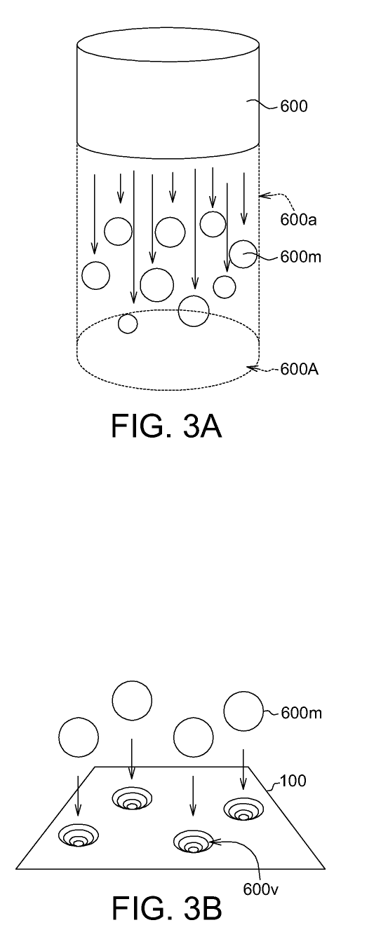

In an alternative embodiment, the nozzle may be an atomized spray nozzle. FIGS. 3A-3B show an atomized spray nozzle 600 for supplying deionized water dissolved CO₂ to a surface of the wafer 100 according to a preferred embodiment of the disclosure. The diameter of the atomized spray nozzle 600 is about 3.6 mm, therefore, as shown in FIG. 3A, the effective cleaning area 600A is relatively large; accordingly, the atomic spray 600a ejected from the atomized spray nozzle 600 can process a relatively large area in a short time, giving rise to an improved cleaning efficiency. In addition, the atomic spray 600a of deionized water with dissolved CO₂ comprises lots of mists 600m, as shown in FIG. 3B, the mass volume 600v of each mist 600m is relatively small and weak, causing less impact to the wafer 100, and hence damage to the surfaces of the wafer 100 is reduced. Despite the impact of the mists 600m being small, with addition of pressurized N₂, the mists 600m of the atomic spray 600a of deionized water with dissolved CO₂ are still provided with excellent abilities of removing particles from the surfaces of the wafer.

Furthermore, in the current step, deionized water is supplied from the nozzle 300 to be applied to the back surface 100b of the wafer 100, which step is prior to the step of applying the chemical solution to the back surface 100b of the wafer 100, which will be discussed later. While deionized water with dissolved CO₂ is applied to the surfaces of the wafer 100, the wafer 100 is rotated concurrently, and the rotating speed is increasing until it reaches a predetermined high speed, such as about 1800 rpm, while the back surface 100b of the wafer 100 is continuously rinsed by deionized water. That is, the step of rotating the wafer 100 and the step of cleaning the wafer 100 are performed simultaneously.

In the present embodiment, the nozzles 200 and 300 are located above the center of the surfaces 100a, 100b of the wafer 100, as shown in FIG. 1B. In such case, for example, as deionized water with dissolved CO₂ is continuously applied to the center of the front surface 100a with the wafer 100 being rotated, a thin film 400 is formed due to the centrifugal force generated by the rotation of the wafer 100, for fully covering the surfaces of the wafer 100 with deionized water with dissolved CO₂ and providing an excellent discharge effect.

And then, the chemical solution, instead of deionized water, is applied to the back surface 100b of the wafer 100 with the nozzle 300, while the front surface 100a is applied with and protected by deionized water with dissolved CO₂ continuously, and the wafer 100 is rotated at the high speed. In an embodiment, the chemical solution may comprise deionized water and HF (hydrofluoric acid) for etching off the oxide residue on the back surface 100b of the wafer 100. In an alternative embodiment, the chemical solution may comprise deionized water, H₂O₂ (hydrogen peroxide), and H₂SO₄ (sulfuric acid) for etching off the metal contamination remained on the back surface 100b of the wafer 100. In the embodiment, the back surface 100b of the wafer 100 is applied with the chemical solution for about 5 minutes.

And then, after the back surface 100b of the wafer 100 is treated with the chemical solution, deionized water is applied to the back surface 100b again, with the nozzle 300, for rinsing off the remaining chemical solution from the back surface 100b. Concurrently, the front surface 100a is kept applied with deionized water with dissolved CO₂ continuously, and the wafer 100 is kept rotated at the high speed.

And then, after the step of applying the chemical solution to the back surface 100b of the wafer 100 is completed, and optionally, after the chemical solution is cleaned off by deionized water, isopropyl alcohol (IPA) is applied to the front surface 100a and the back surface 100b of the wafer 100, with the nozzles 200 and 300, for drying the wafer 100, and the wafer 100 is kept rotated at the high speed. However, the solvent applied to the surfaces 100a and 100b of the wafer 100 for drying purposes may vary depending on the conditions applied, as long as the solvent utilized may help deionized water vaporize quickly, and is not limited to IPA aforementioned.

It is to be noted that, according to the embodiments of the present disclosure, a scrub cleaning process is not required between the chemical cleaning step and the drying step, or between any steps in the cleaning process. The charges produced from the plasma process and impurities from preceding manufacturing processes have been fully removed in the cleaning process without performing a scrub cleaning step. As such, the cleaning process for the wafer 100 is simplified, and the cost is reduced. The wafer 100 is ready for subsequent manufacturing processes as it is dried.

Next, as shown in FIG. 1C, after the step of cleaning the wafer 100 is completed, the charges are released, and the surfaces of the wafer 100 are dried. And then, necessary manufacturing processes, such as a photoresist and etching process for forming patterned metal layers or aluminum pads, may be performed on the front surface 100a of the wafer 100.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for treating a wafer, comprising:
performing a plasma process on a front surface of the wafer; and
cleaning the wafer, comprising:
applying deionized water with dissolved CO₂ to the front surface of the wafer; and
applying a chemical solution to a back surface, opposite to the front surface, of the wafer.

2. The method for treating the wafer according to claim 1, wherein the chemical solution comprises deionized water and HF.

3. The method for treating the wafer according to claim 1, wherein the chemical solution comprises deionized water, H₂SO₄, and H₂O₂.

4. The method for treating the wafer according to claim 1, wherein the step of cleaning the wafer further comprises:
applying deionized water to the back surface of the wafer prior to the step of applying the chemical solution to the back surface of the wafer.

5. The method for treating the wafer according to claim 1, wherein the step of cleaning the wafer further comprises:
applying isopropyl alcohol to the front surface and the back surface of the wafer after the step of applying the chemical solution to the back surface of the wafer.

6. The method for treating the wafer according to claim 1, wherein the step of cleaning the wafer further comprises:
applying deionized water to the back surface of the wafer after the step of applying the chemical solution to the back surface of the wafer.

7. The method for treating the wafer according to claim 1, wherein the back surface of the wafer is applied with the chemical solution for about 5 minutes.

8. The method for treating the wafer according to claim 1, wherein the deionized water dissolved with CO₂ and the chemical solution are applied independently with a jet nozzle, an atomized spray nozzle, or a mega-sonic nozzle.

9. The method for treating the wafer according to claim 1, wherein IPA is applied to the front surface and the back surface of the wafer with a jet nozzle, an atomized spray nozzle, or a mega-sonic nozzle.

10. The method for treating the wafer according to claim 1, wherein the front surface of the wafer is formed of a dielectric layer.

11. The method for treating the wafer according to claim 10, wherein the dielectric layer is formed by the plasma process.

12. The method for treating the wafer according to claim 10, wherein the thickness of the dielectric layer is about 12 nm.

13. The method for treating the wafer according to claim 1, wherein the plasma process comprises at least one of a plasma-enhanced chemical vapor deposition (PECVD) process, a high density plasma chemical vapor deposition (HDPCVD) process, or a sputtering process.

14. The method for treating the wafer according to claim 1, further comprising:
performing a photoresist and etching process on the front surface of the wafer after the step of cleaning the wafer.

15. The method for treating the wafer according to claim 1, further comprising:
rotating the wafer.

16. The method for treating the wafer according to claim 15, wherein the step of rotating the wafer and the step of cleaning the wafer are performed simultaneously.
